(19) United States
(12) Patent Application Publication
(10) Pub. No.: US 2011/0069574 A1
(43) Pub. Date: Mar. 24, 2011

(54) SEMICONDUCTOR MEMORY DEVICE

(75) Inventor: Osamu HIRABAYASHI, Tokyo (JP)

(73) Assignee: KABUSHIKI KAISHA TOSHIBA, Tokyo (JP)

(21) Appl. No.: 12/719,707

(22) Filed: Mar. 8, 2010

(30) Foreign Application Priority Data
Sep. 18, 2009 (JP) 2009-216880

(51) Int. Cl. G11C 5/14; G11C 8/08

(52) U.S. Cl. 365/226; 365/230.06

(57) ABSTRACT

A semiconductor memory device includes a memory cell array, a word line driver, and a bit line booster. The memory cell array has multiple word lines WL, multiple bit line pairs BL, and multiple memory cells MC provided at the respective intersections of the word lines WL and the bit line pairs BL. The word line driver drives a selected word line WL to a positive voltage VWL when data is written to the memory cells MC. The bit line booster drives a selected bit line pair BL to a negative voltage VBL corresponding to the voltage VWL when data is written to the memory cells MC.

### CROSS REFERENCE TO RELATED APPLICATION

This application is based upon and claims the benefit of priority from the prior Japanese Patent Application No. 2009-216880, filed on Sep. 18, 2009, the entire contents of which are incorporated herein by reference.

### FIELD OF THE INVENTION

The invention relates to a semiconductor memory device, and more specifically, a semiconductor memory device, such as a static random access memory (SRAM), which operates at a low voltage.

### DESCRIPTION OF THE BACKGROUND

Lowering power consumption of LSIs used in mobile devices is demanded in order to extend battery run time. Reducing a supply voltage is effective for lowering the power consumption. However, an increase in variations in element characteristic due to advancement of scaling in recent years has been decreasing an operation margin of a static random access memory (SRAM) used in an LSI, so that an operating voltage of the SRAM is difficult to reduce. Accordingly, the operating voltage of an SRAM works as a rate-limiting factor, and thus hinders reduction in the supply voltage of the entire LSI.

Fault modes of an SRAM cell include a disturb fault in which data corruption occurs due to instability caused in an internal node of a cell at the time of word line selection, and a write fault in which the state of a cell fails to be inverted at the time of data writing. Additionally, when an SRAM operates at a low voltage, deterioration of the write characteristic of the SRAM becomes pronounced.

In order to address the problem, there has been proposed a technique to make one of two bit lines connected to an SRAM cell have a negative potential during a write operation (K. Nii et. al., “A 45-nm Single-port and Dual-port SRAM family with Robust Rear/Write Stabilizing Circuitry under DVFS Environment”, 2008 Symposium on VLSI Circuits Digest of Technical Papers, P212-213). With the technique, a bootstrap circuit makes a bit line have a negative voltage, which in turn raises a gate-to-source voltage of a transfer N-channel MOS transistor of the SRAM cell. As a result, the write characteristic of an SRAM is improved.

However, even if the write characteristic is improved with the technique described above, a chip manufactured with the disturb characteristic of the chip lowered due to changes in process conditions has a problem that the operating voltage is rate-limited by aggravation of the disturb characteristic.

### SUMMARY OF THE INVENTION

According to an aspect of the invention is provided a semiconductor memory device, comprising a memory cell array having a plurality of word lines, a plurality of bit lines intersecting the plurality of word lines, and a plurality of memory cells connected to the intersections of the plurality of word lines and the plurality of bit lines, a word line driver to drive a selected word line to a positive first voltage when data is written to the memory cells; and a bit line driver to drive a selected bit line to a negative second voltage corresponding to the first voltage when data is written to the memory cells.

According to another aspect of the invention is provided a semiconductor memory device, comprising a memory cell array having a plurality of word lines, a plurality of bit lines intersecting the plurality of word lines, and a plurality of memory cells connected to the intersections of the plurality of word lines and the plurality of bit lines, a word line driver to drive a selected word line to a positive first voltage when data is written to the memory cell; and a bit line driver to drive a selected bit line to a negative second voltage corresponding to the first voltage when data is written to the memory cell, wherein the word line driver includes, an inverter circuit formed of a first P-channel insulated gate field effect transistor and a first N-channel insulated gate field effect transistor, and a step-down unit connected to an output terminal of the inverter circuit, and wherein when a word line is selected, the word line driver output a midpoint potential between a supply voltage and a ground voltage as the first voltage by use of the first P-channel insulated gate field effect transistor and the step-down unit.

According to another aspect of the invention is provided a semiconductor memory device, comprising a regulator to step down a supply voltage and to generate a positive first voltage, and a memory block to receive the first voltage from the regulator to perform writing and reading of data, wherein the memory block includes, a memory cell array having a plurality of word lines, a plurality of bit lines intersecting the plurality of word lines, and a plurality of memory cells connected to the intersections of the plurality of word lines and the plurality of bit lines, a word line driver to drive a selected word line to the positive first voltage when data is written to the memory cells, and a bit line driver to drive a selected bit line to a negative second voltage corresponding to the first voltage when data is written to the memory cells.

### BRIEF DESCRIPTION OF THE DRAWINGS

FIG. 1 is a block diagram showing a semiconductor memory device according to a first embodiment of the invention.

FIG. 2 is a circuit diagram of an SRAM cell array according to the first embodiment of the invention.

FIG. 3 is a circuit diagram of a bit line booster according to the first embodiment of the invention.

FIG. 4 is a view showing a relation among an SRAM cell fraction defective (sigma), a voltage VWL of a selected word line WL, and a voltage VBL of a selected bit line BL, under an FS condition according to the first embodiment of the invention.

FIG. 5 is a view showing a relation among the SRAM cell fraction defective (sigma), the voltage VWL of the selected word line WL, and the voltage VBL of a selected bit line BL, under an SF condition according to the first embodiment of the invention.

FIG. 6 is a view showing a relation between VWL and VBL in association with characteristic variations in manufacturing of the SRAM cells according to the first embodiment of the invention.

FIG. 7 is a block diagram of a semiconductor memory device according to a second embodiment of the present invention.

FIG. 8 is a circuit diagram showing one example of a word line driver according to the second embodiment of the invention.

FIG. 9 is a circuit diagram showing another example of the word line driver according to the second embodiment of the invention.

FIG. 10 is a circuit diagram of a bit line booster according to the second embodiment of the invention.

FIG. 11 is a view showing a process and temperature dependencies of the voltage VWL according to the second embodiment of the invention.

FIG. 12 is a view showing variation ΔVWL(V) of the voltage VWL under each condition shown in FIG. 11 according to the second embodiment of the invention.

### DETAILED DESCRIPTION OF THE INVENTION

A semiconductor memory device according to embodiments of the invention will be described in detail hereinafter with reference to the drawings.

A first embodiment of the semiconductor memory device according to the invention will be described in detail hereinafter with reference to the drawings.

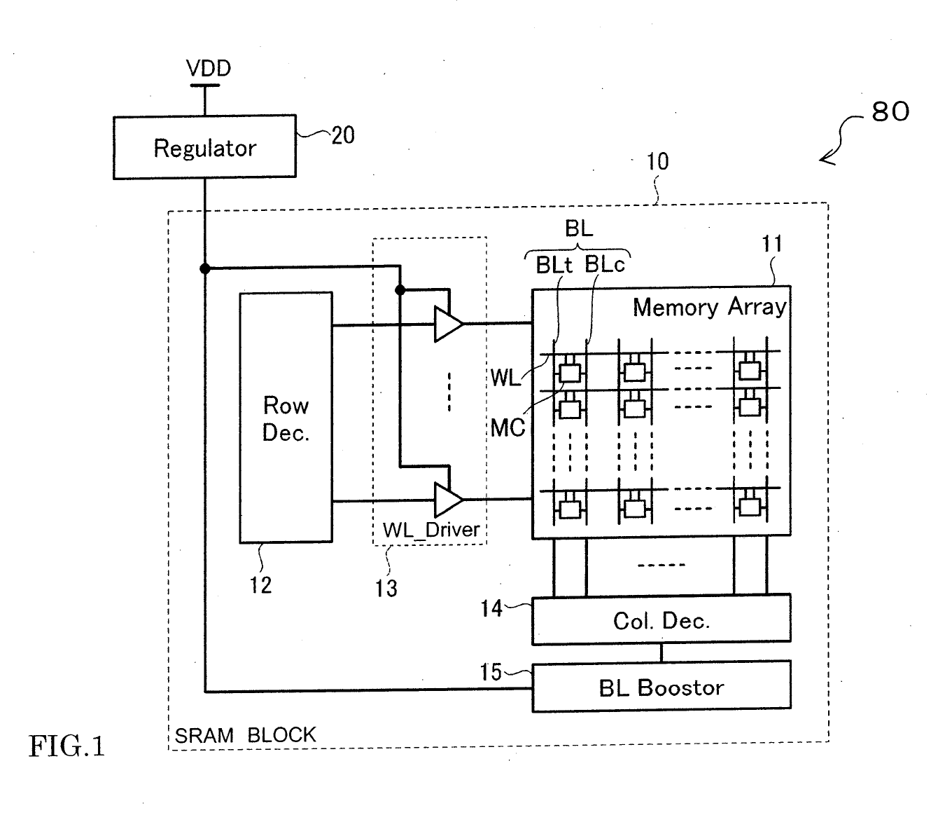

An overall configuration of the semiconductor memory device according to the first embodiment will be described with reference to FIG. 1. FIG. 1 is a block diagram showing the semiconductor memory device according to the first embodiment. In the embodiment, a word line driver and a bit line booster are provided in an SRAM block.

As shown in FIG. 1, an SRAM (Static Random Access Memory) block 10 and a regulator 20 are provided in a semiconductor memory device 80. The SRAM block 10 is configured to enable writing and reading of data. The regulator 20, to which a supply voltage VDD is supplied, lowers the supply voltage VDD, generates a positive voltage VWL, and supplies the generated positive voltage VWL to the SRAM block 10. Although the SRAM block 10 and the regulator 20 are provided inside the same LSI chip, the regulator 20 may be provided outside the LSI chip.

In the SRAM block 10, a memory cell array 11, a row decoder 12, a word line driver 13, a column decoder 14, and a bit line booster 15 are provided.

The memory cell array 11 includes multiple word lines WL, multiple bit line pairs BL consisting of bit lines BLt, BLc, and multiple SRAM cells MC provided at the respective intersections of the word lines WL and the bit lines BL.

The row decoder 12 selects a word line WL on the basis of a row address signal inputted when data is written. The word line driver 13 is supplied with a voltage VWL from the regulator 20, and applies the voltage VWL to the selected word line WL.

The column decoder 14 selects a bit line pair BL on the basis of a column address signal inputted when data is written. The bit line booster 15 is supplied with a voltage VWL, which is a first positive voltage from the regulator 20, and generates a voltage VBL, which is a second negative voltage corresponding to the voltage VWL. The bit line booster 15 applies a negative voltage VBL to one of the selected bit line pair BL. Then, the supply voltage VDD is applied to the other of the bit line pair BL.

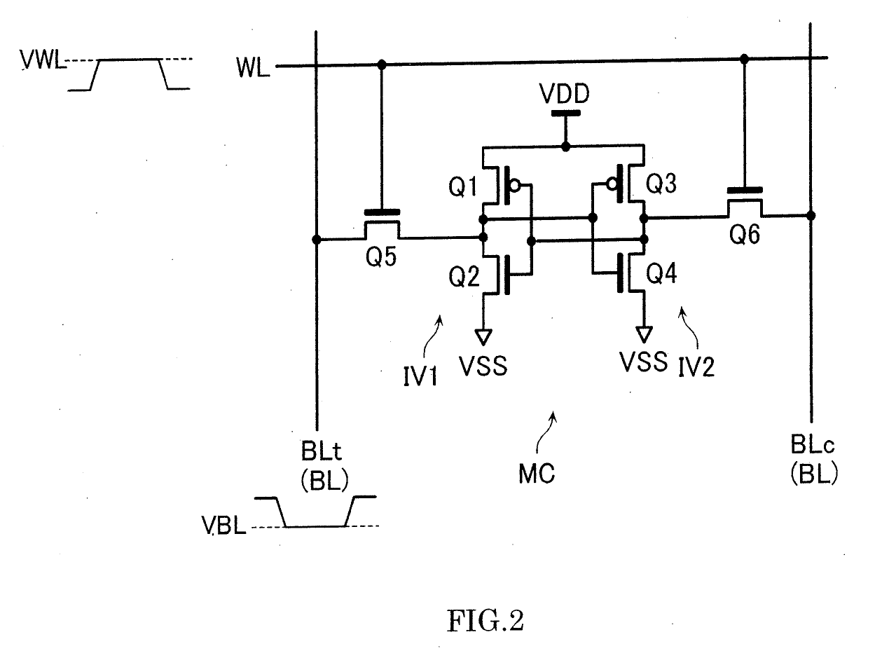

A circuit configuration of the SRAM cell will be described with reference to FIG. 2. FIG. 2 is a circuit diagram of the SRAM cell MC.

As shown in FIG. 2, the SRAM cell MC is formed of a 6 transistor type memory cell, for example. The 6 transistor type memory cell has a first inverter IV1 and a second inverter IV2. The first inverter IV1 includes a P-channel MOS transistor Q1 and an N-channel MOS transistor Q2. The P-channel MOS transistor Q1 and the N-channel MOS transistor Q2 are connected in series between a power line VDD and a ground line VSS, the P-channel MOS transistor Q1 having a source on the power line VDD side, the N-channel MOS transistor Q2 having a source on the ground line VSS side. The second inverter IV2 includes a P-channel MOS transistor Q3 and an N-channel MOS transistor Q4. The P-channel MOS transistor Q3 and the N-channel MOS transistor Q4 are connected in series between the power line VDD and the ground line VSS, the P-channel MOS transistor Q3 having a source on the power line VDD side, the N-channel MOS transistor Q4 having a source on the ground line VSS side. Input and output of the inverters IV1 and IV2 are mutually connected and form a data retention unit. A first transfer transistor Q5 is connected between the bit line BLt and an output terminal of the first inverter IV1, and a second transfer transistor Q6 is connected between the bit line BLc and an output terminal of the second inverter IV2. A gate terminal of each of the first and second transfer transistors Q5, Q6 is connected to the word line WL.

Here, a MOS transistor is also referred to as a MOSFET (Metal Semiconductor Field Effect Transistor), and a gate insulator of the MOSFET is formed of a silicon oxide film (SiO₂). A MIS transistor is also referred to as a MISFET (Metal Insulator Semiconductor Field Effect Transistor), and a gate insulator of the MISFET is formed of a composite membrane of a silicon oxide film (SiO₂) and any of other insulating films, or is formed of an insulating film other than a silicon oxide film (SiO₂) or the like. The MOS transistor and MIS transistor are also referred to as Insulated Gate Field Effect Transistors.

In addition, a write operation using the 6 transistor type memory cell is performed both on the bit lines BLt and BLc, while a read operation may be a single-end read in which a read operation is performed from either one of the bit lines BLt, BLc.

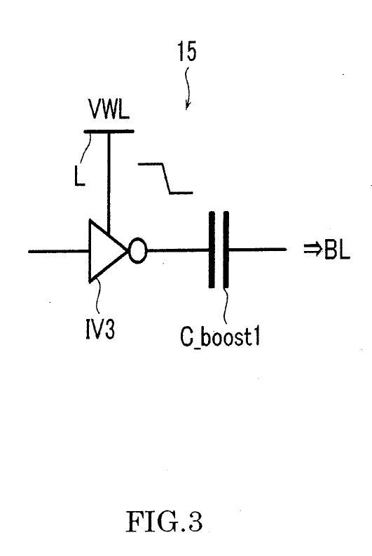

A circuit configuration of the bit line booster will be described hereinafter with reference to FIG. 3. FIG. 3 is a circuit diagram of the bit line booster 15.

As shown in FIG. 3, the bit line booster 15 includes an inverter IV3 and a capacitor C_boost 1. The inverter IV3 and the capacitor C_boost 1 are connected in series. The voltage VWL is applied to the power line L of the inverter IV3. The capacitor C_boost1 applies the negative voltage VBL to any one of the bit line pair BL by a coupling based on the voltage of an output terminal of the inverter IV3. The amplitude of the negative voltage VBL generated by a capacity coupling is proportional to the amplitude of the voltage of an output terminal of the inverter IV3. In fact, this represents that the lower the voltage VWL level is, the higher the voltage VBL level can be set.

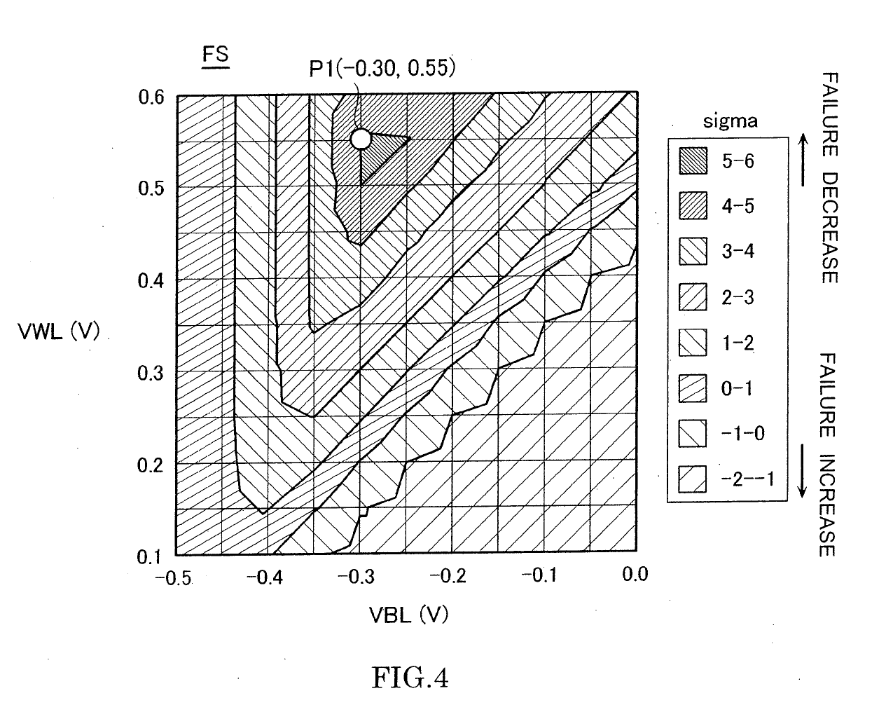

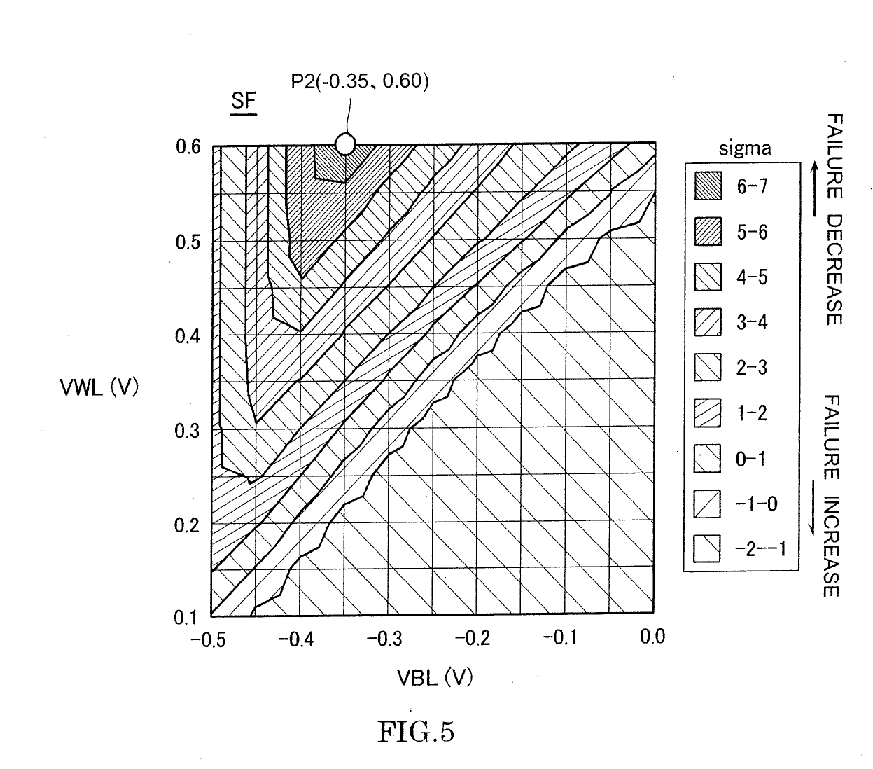

Optimal voltage application conditions according to characteristics of the SRAM cell generated depending on manufacturing processes will be described hereinafter with reference to FIGS. 4 to FIG. 6. FIGS. 4 and 5 show a relation among the fraction defective (sigma) of the SRAM cell MC and the voltages VWL and VBL under the FS condition and SF condition, respectively. Now, the FS condition and SF condition show characteristic variations, due to manufacturing processes, of the N-channel MOS transistor and the P-channel MOS transistor which form the SRAM cell MC. Under the FS condition, the N-channel MOS transistor changes to the side with larger current driving force (Fast) and the P-channel MOS transistor changes to the side with smaller current driving force (Slow). Under the SF condition, the N-channel MOS transistor changes to the side with smaller current driving force (Slow), and the P-channel MOS transistor changes to the side with larger current driving force (Fast).

Negative voltage VBL is applied to one of the bit line pair BL. Thus, as the source-to-gate voltage and the source-to-drain voltage of any one of the transistors Q5, Q6 of the SRAM cell MC increase, writing of data becomes easier and the write fraction defective of the SRAM cell MC decreases. However, if negative VBL is set to exceed threshold voltage of each of the transistors Q5, Q6, the transistors Q5, Q6 enter a conduction state even if the SRAM cell MC is unselected (the word line WL is 0V). In the selected column, this results in erroneous writing to a cell in an unselected row, and the fraction defective of the SRAM cell MC increases.

Under the FS condition, during writing, if negative voltage VBL is applied to one of the bit line pair BL and the writing margin is improved, a disturb fault is rate-limited. Thus, during writing, if negative voltage VBL is applied to one of the bit line pair BL, and voltage VWL which is set to the level lower than the supply voltage VDD is applied to the word line WL, the disturb fault decreases. Adjustment of the voltage VWL and the voltage VBL together would provide a lower fraction defective than adjustment of the voltage VBL only. Under the FS condition, as shown by the point P1 of FIG. 4, for example, the fraction defective of the SRAM cell MC is smallest when voltage VWL=0.55V and voltage VBL=−0.30V.

Under the SF condition, as driving force of each of the N-channel MOS transistors Q5, Q6 is small, and a disturb fault does not easily occur, there is no need to lower the voltage VWL level. Under the SF condition, as threshold voltage of each of the transistors Q5, Q6 of the SRAM MC is high, a lower fraction defective can be achieved if the voltage VBL level is set higher than the FS condition. Under the SF condition, as shown in the point P2 of FIG. 5, for example, the fraction defective of the SRAM cell MC is smallest when voltage VWL=0.60 V and voltage VBL=−0.35V.

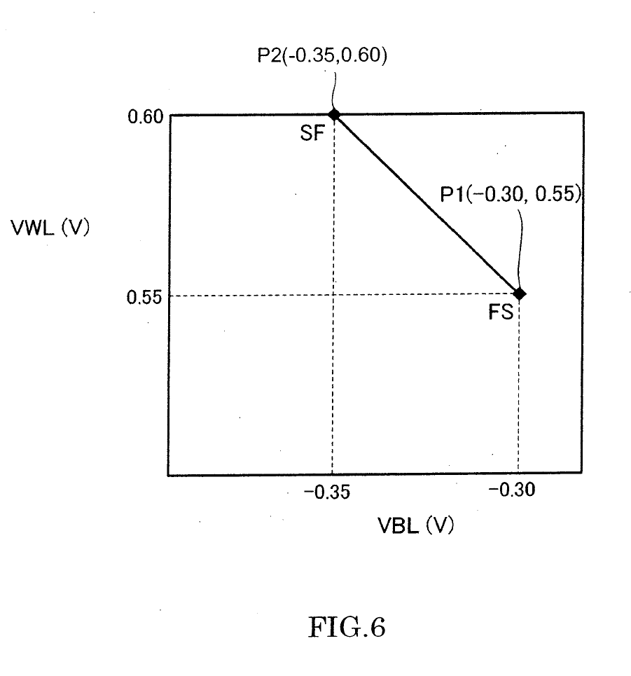

A relation between voltages VWL, VBL in association with the characteristic variations in manufacturing of SRAM cells will be described. FIG. 6 is a view showing a relation between optimal voltages VWL, VBL in accordance with the characteristics of the SRAM cell MC which are determined from the points P1, P2 shown in FIG. 4 and FIG. 5.

As shown in FIG. 6, voltage VBL and voltage VWL at which the fraction defective of the SRAM cell MC is smallest are proportionate. The optimal levels of voltages VBL, VWL varies depending on the FS condition and SF condition. Under the FS condition, the fraction defective of the SRAM cell MC can be minimized by setting voltage VWL lower and voltage VBL higher than those under the SF condition.

A relation between voltage VBL and voltage VWL will be described more specifically. In the SRAM cell MC, considering the balance of data writing, it is desirable to keep constant a current ratio between each of the N-channel MOS transistors Q5, Q6 and each of the P-channel MOS transistors Q1, Q3, irrespective of changes in the manufacturing conditions. Thus, the voltage VWL is adjusted to satisfy the expression 1 below. Here, signs Vthn, Vthp respectively denote threshold voltages of each of the N-channel MOS transistors Q5, Q6 and each of the P-channel MOS transistors Q1, Q3. Signs βn, βp are constants.

{βn(VWL−Vthn)²}/{βp(VDD−Vthp)²}=constant (1)

Here, if the current variation of each of the N-channel MOS transistors Q5, Q6 is more dominant than the current variation of each of the P-channel MOS transistors Q1, Q3 due to the changes in the manufacturing conditions, the denominator of the expression 1 can be considered constant. Therefore, if VWL is determined so that VWL−Vthn is constant, the condition for the expression 1 to be constant is satisfied. Then, if VWL−Vthn=A (constant), a relation of the following expression 2 is derived:

VWL=Vthn+A (2)

In addition, since the voltage VBL is about the threshold voltage Vthn of each of the N-channel MOS transistors Q5, Q6, the voltage VBL can be expressed by the following expression 3:

−VBL=Vthn (3)

Thus, with the expressions 2 and 3, a relation between the voltage VWL and voltage VBL can be expressed by the expression (4) shown below:

VWL=−VBL+A (4)

For the semiconductor memory device 80 according to the first embodiment, the level of the voltage VWL and the level of the voltage VBL are set so that these levels will be in a relation shown in FIG. 6, on the basis of the characteristic variations in manufacturing of the SRAM cell MC. Specifically, the semiconductor memory device 80 is configured such that the lower the voltage VWL level is, the higher the voltage VBL level is. That is to say, the voltage VWL level and the voltage VBL level are set so that the relation of the above expression 4 can be satisfied. In addition, the regulator 20 may be of a type of digitally controlling the voltage VWL level on a line connecting the points P1 and P2, or a type configured to enable continuous (analog) control of the voltage VWL level.

Since the semiconductor memory device 80 according to the first embodiment is configured such that the negative voltage VBL can be set depending on positive voltage VWL, deterioration of a write characteristic can be prevented irrespective of changes in process conditions, and the write operation can be executed even at a low voltage.

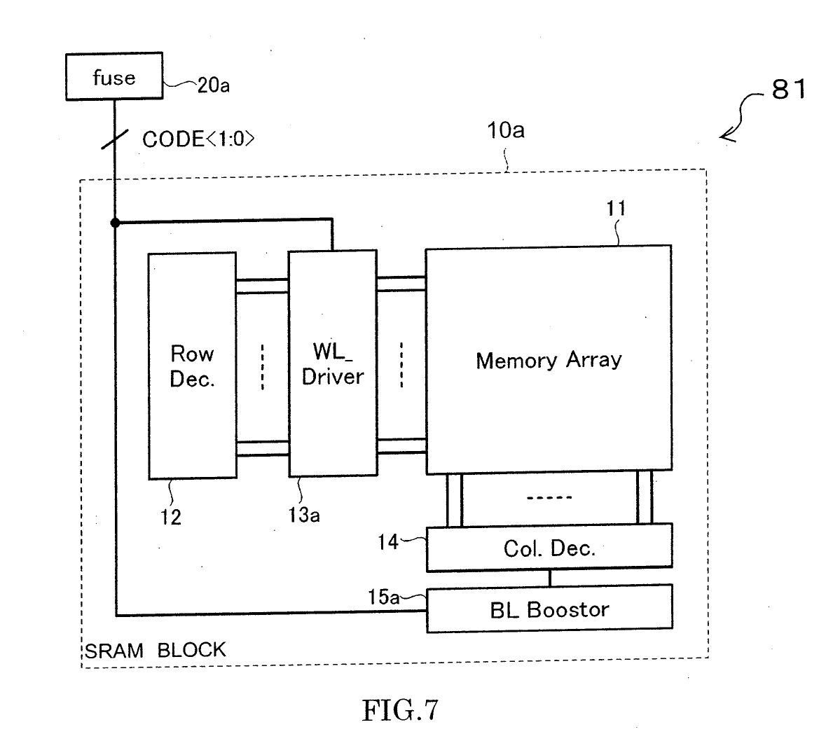

A semiconductor memory device according to a second embodiment of the invention will be described with reference to the drawings. FIG. 7 is a block diagram showing a semiconductor memory device.

In the embodiment, a voltage setting unit is provided instead of the regulator of the first embodiment, and a word line driver and a bit line booster, which are different from the first embodiment, are provided. Here, the voltage setting unit is composed of a fuse circuit, for example. The voltage setting unit may be also composed of a process-monitored circuit, and the like. In the following, in a configuration similar to the first embodiment, the same reference numerals are given to the same portions. Here, descriptions on the same portions are omitted, and descriptions on different portions will be described.

As shown in FIG. 7, an SRAM block 10a and a fuse circuit 20a are provided in a semiconductor memory device 81. In the SRAM block 10a, a memory cell array 11, a row decoder 12, a word line driver 13a, a column decoder 14, and a bit line booster 15a are provided.

A fuse circuit 20a has information on the level of the voltage VWL of the selected word line WL and the level of the voltage VWL of the selected bit line pair BL. The fuse line 20a outputs signals CODE <0 (zero)> and CODE <1> to the word line driver 13a and the bit line booster 15a. The signals CODE <0>, CODE <1> have a voltage which is set depending on the level of the voltage VWL of the selected word line WL and the level of the voltage VWL of the selected bit line pair BL. The fuse circuit 20a is provided in a voltage setting unit and stores voltage setting information.

The word line driver 13a and the bit line booster 15a set the voltage VWL and voltage VBL on the basis of the signals CODE <0>, CODE <1>. Similar to the first embodiment, the word line driver 13a and the bit line booster 15a set the voltage VWL and voltage VBL on the basis of the characteristic variations in manufacturing of the SRAM cell MC. The word line driver 13a and the bit line booster 15a set the voltage VBL to higher level as the voltage VWL level is lower, and set the voltage VWL and voltage VBL to satisfy the relation of [expression 4] above (shown in the first embodiment).

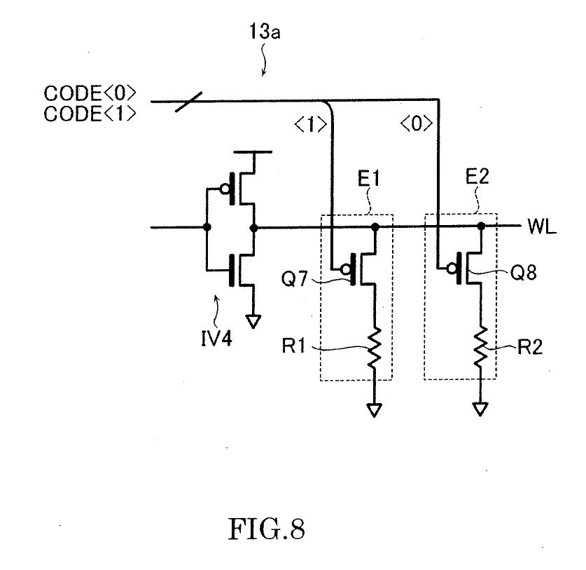

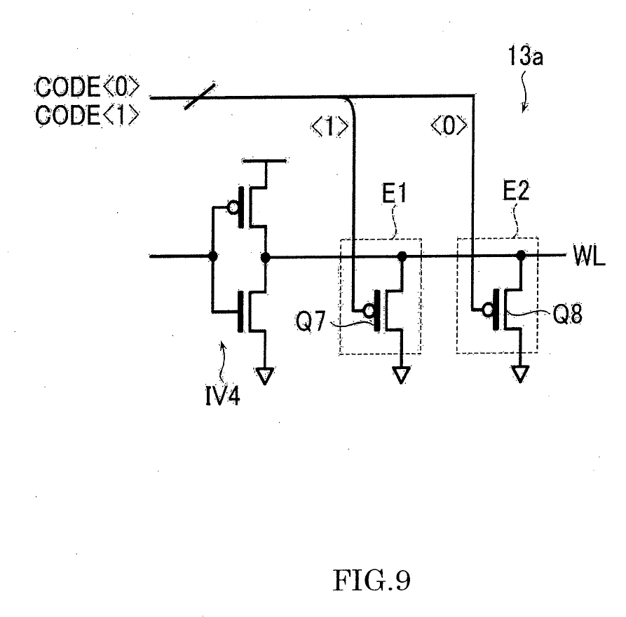

The word line driver will be described hereinafter with reference to FIGS. 8 and 9. FIG. 8 is a circuit diagram showing one example of the word line driver 13. FIG. 9 is a circuit diagram showing another example of the word line driver 13.

As shown in FIG. 8, the word line driver 13a includes an inverter IV4 and step-down units E1, E2 which are connected between an output terminal of the inverter IV4 and a ground potential. The output terminal of the inverter IV4 is connected to the word line WL and transfers the voltage VWL to the word line WL. The step-down units E1, E2 enter a conduction state or a non-conduction state on the basis of the signals CODE <0>, CODE <1>, and step down the voltage of the output terminal of the inverter IV4. Accordingly, the step-down units E1, E2 set the voltage VWL, depending on a balance between the P-channel MOS transistor for a pull-up of the inverter IV4 and the P-channel MOS transistors Q7, Q8 for a pull-down of the respective step-down units E1, E2. The voltage VWL changes in stages by controlling each of the 2 step-down units E1, E2 to the conduction state and the non-conduction state.

The step-down unit E1 is formed of the P-channel MOS transistor Q7 and a resistance element R1 which are connected in series. The P-channel MOS transistor Q7 has a source connected to an output terminal of the inverter IV4, a drain connected to one end of the resistance element R1, and a gate receive an input of the signal CODE <1> from the fuse circuit 20a. The other end of the resistance element R1 is grounded. Similar to the step-down unit E1, the step-down unit E2 is formed of the P-channel MOS transistor Q8 and the resistant element R2, which are connected in series. The P-channel MOS transistor Q8 has a gate receive an input of the signal CODE <0> from the fuse circuit 20a. The resistance elements R1, R2 prevent to change a current value of the P-channel MOS transistors Q7, Q8 caused by process fluctuations. In the FIG. 8, the P-channel MOS transistors Q7, Q8 are provided at the side of the word line. The resistance elements R1, R2 are provided at the side of the ground potential. But, The resistance elements R1, R2 may be provided at the side of the word line. The P-channel MOS transistors Q7, Q8 may be provided at the side of the ground potential.

The word line driver may have a configuration other than the configuration shown in FIG. 8. That is to say, as shown in FIG. 9, the word line driver 13a has an inverter IV4, and step-down units E1, E2 which are connected between the output terminal of the inverter IV4 and the ground potential. The step-down units E1, E2 are configured such that the resistance elements R1, R2 shown in FIG. 8 are omitted from the configuration shown in FIG. 8. In this case, each of the P-channel MOS transistors Q7, Q8 has a source connected to the output terminal of the inverter IV4 and a drain grounded.

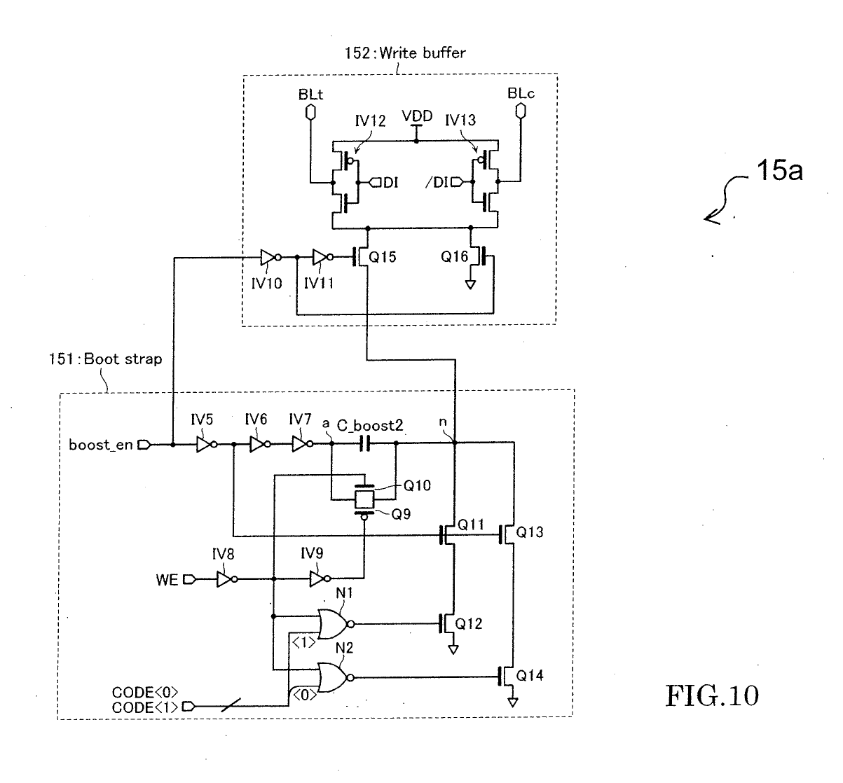

The bit line booster will be described hereinafter with reference to FIG. 10. FIG. 10 is a circuit diagram of the bit line booster.

As shown in FIG. 10, the bit line booster 15a has a bootstrap circuit 151 to adjust a value of the voltage to be applied to a bit line pair BL, and a write buffer circuit 152 provided between the bootstrap circuit 151 and the bit line pair BL.

The bootstrap circuit 151 has inverters IV5 to IV9, transistors Q9 to Q14, NOR circuits N1, N2, and a capacitor C_boost 2 for bootstrap. An output terminal of the inverter IV5 is connected to a node a on the side of one end of the capacitor C_boost2 by way of inverters IV6 and IV7. Now, a node on the side of the other end of the capacitor C_boost2 is a node n. The P-channel MOS transistor Q9 and the N-channel MOS transistor Q10 are connected between the node a and the node n, in parallel with the capacitor C_boost2. A write enable signal WE is inputted to a gate of the transistor Q9 by way of inverters IV8, IV9, and a write enable signal WE is inputted to a gate of the transistor Q10 by way of the inverter IV8.

The node n is connected to a ground line VSS by way of N-channel MOS transistors Q11, Q12 to discharge the node n. The node n is connected to the ground line VSS by way of N-channel MOS transistors Q 13, Q14 to discharge the node n. A boost enable signal boost_en is inputted to a gate of each of the transistors Q11, Q13 by way of the inverter IV5, and output signals from NOR circuits N1, N2 are inputted to gates of the transistors Q12, Q14, respectively. In the NOR circuit N1, the write enable signal WE is inputted to one input terminal by way of the inverter IV8, and a signal CODE <1> is inputted to the other input end. In the NOR circuit N2, the write enable signal WE is inputted to one input terminal by way of the inverter IV8, and a signal CODE <0> is inputted to the other input end.

The bootstrap circuit 151 has a function to change potential of the node n to negative when a write operation is executed, apply the negative potential of the node n to the bit line pair BL by way of a write buffer circuit 152, and drive one of the bit lines BLt or BLc to the negative voltage. The bootstrap circuit 151 includes charging/discharging circuits (transistors Q11 to Q14) connected to one end of the capacitor C_boost2. By adjusting charging or discharging current of the charging/discharging circuit on the basis of the signals CODE <1>, <0>, the bootstrap circuit 151 adjusts a voltage which appears on one end of the capacitor element C_boost2 when the other end of the capacitor element C_boost2 is inverted from high level to low level.

The write buffer circuit 152 includes inverters IV10 to IV13, and N-channel MOS transistors Q15, Q16. The boost enable signal boost_en is inputted to not only a gate of the transistor Q15 by way of the inverters IV10, IV11, but also a gate of the transistor Q16 by way of the inverter IV10. A source of the transistor Q15 is connected to the node n of the bootstrap circuit 151, and a source of the transistor Q16 is connected to the ground line VSS. The inverters IV12, IV13 are connected respectively between the power line VDD and the drains of the transistors Q15, Q16, and data signals DI, /DI which are different from each other are respectively inputted to input terminals. In addition, output terminals of the inverters IV12, IV13 are connected to the bit lines BLt, BLc, respectively.

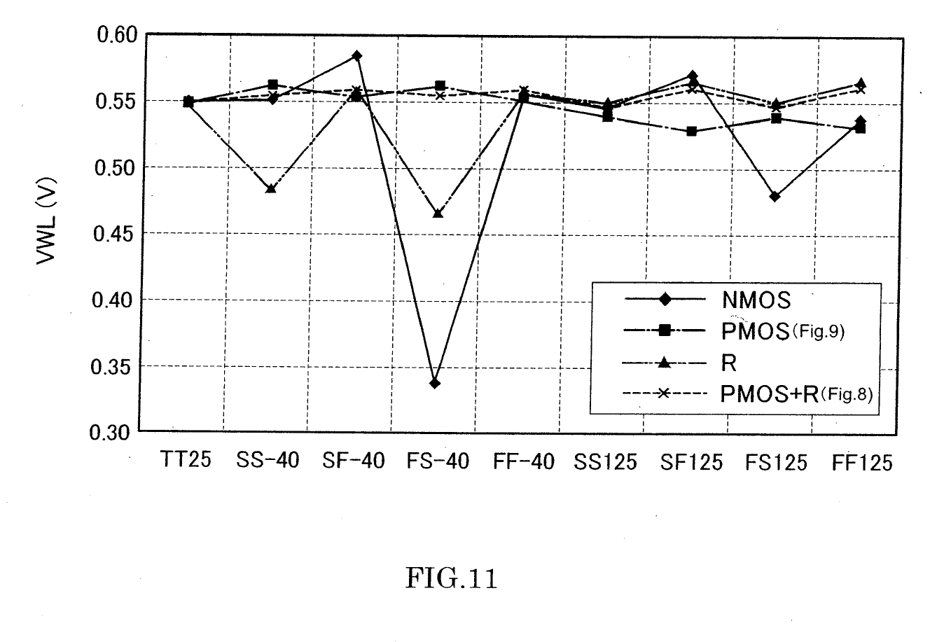

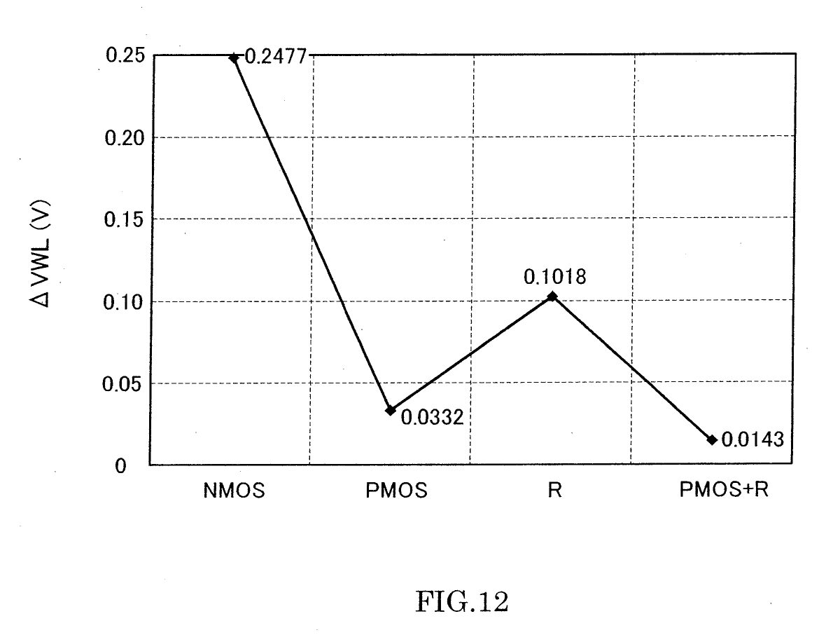

The process and temperature dependencies of the word line voltage VWL will be described hereinafter with reference to FIG. 11 and FIG. 12. FIG. 11 is a view showing a change in the word line voltage VWL, depending on the manufacturing and temperature conditions. FIG. 12 is a view showing variation ΔVWL of the word line voltage VWL for each one of different types of step-down units of FIG. 11.

As shown in FIG. 11, the first halves of respective signs, “TT”, “SS”, “SF”, “FS”, “FF”, show characteristics of the transistors due to changes in the manufacturing conditions, the first character showing the characteristics of the N-channel MOS transistor, and the second character showing the characteristics of the P-channel MOS transistor. “T” denotes standard (typical). “S” denotes small driving force (Slow). “F” denotes large driving force (Fast). The second halves “25”, “−40”, “125” denote the temperature conditions at the time of driving.

In FIG. 11, a step-down unit of the word line driver 13a is simulated in 4 types, namely the N-channel MOS transistor, the P-channel MOS transistor (type of FIG. 9), the resistance element R, and a combination of the P-channel MOS transistor and the resistance element (type of FIG. 8). Each type was adjusted so that VWL=0.55V should be applied to the word line WL under the condition of “TT 25” (both the N-channel MOS transistor and the P-channel MOS transistor had standard characteristics and was driven at 25° C.), and the simulation was conducted to find out how the word line voltage VWL varied under other manufacturing and temperature conditions.

As is obvious from FIG. 11 and FIG. 12, when a combination of the P-channel MOS transistor and the resistance element was used, the dependency on the manufacturing conditions and temperature conditions of the word line voltage VWL was smallest. When the P-channel MOS transistor was used alone as the step-down unit, the dependency on the manufacturing conditions and temperature conditions was relatively small. The reason is considered as follows. Both a pull-up element and a pull-down element to determine the word line voltage VWL are the P-channel MOS transistors, and thus variation due to the manufacturing conditions and the temperature conditions appears equally in both P-channel MOS transistors, and thereby the variation is cancelled.

In contrast, when the N-channel MOS transistors were used as step-down units, a decrease in the word line potential was pronounced especially under “FS” condition in which the driving force of the N-channel MOS transistor is large and the driving force of the P-channel MOS transistor is small. It is considered that this is a result of the effect of the N-channel MOS transistor for a pull-down being greater than the effect of the P-channel MOS transistor for a pull-up, which determines the word line voltage VWL. For similar reasons, variation was large when only the resistance element was used as a step-down unit.

It can be seen from the above result that for the step-down unit of the word line driver 13a, which generates the word line voltage VWL, the type shown in FIG. 8 or FIG. 9 in which the P-channel MOS transistors Q7, Q8 are used is desirable.

In addition to the effect of the first embodiment, the semiconductor memory device 81 according to the second embodiment can control voltage VWL of the word line WL in stages, depending on the signals CODE <0>, CODE <1>.

As shown in FIG. 11 and FIG. 12, the step-down units E1, E2 of the second embodiment can generate the voltage VWL in a stable manner. Therefore, the semiconductor memory device 81 according to the second embodiment can perform more stabilized control, independent of the process condition.

Although the embodiments of the semiconductor memory device have been described so far, the invention should not be limited to the above embodiments, and various changes, additions, replacements or the like can be made without departing from the scope of the intent of the invention.

Although MOS transistors are used in the semiconductor memory device in the embodiments 1 and 2, MIS transistors may be used instead.

What is claimed is:

1. A semiconductor memory device comprising:
a memory cell array comprising a plurality of word lines, a plurality of bit lines intersecting the plurality of word lines, and a plurality of memory cells connected to the intersections of the plurality of word lines and the plurality of bit lines;
a word line driver configured to drive a selected word line to a positive first voltage when data is written to the memory cells; and
a bit line driver configured to drive a selected bit line to a negative second voltage corresponding to the first voltage when the data is written to the memory cells.

2. The semiconductor memory device of claim 1, wherein each memory cell comprises an SRAM cell comprising a data retention module, and a transfer transistor connected between the data retention module and one of the bit lines, the transfer transistor comprising a gate connected to one of the word lines.

3. The semiconductor memory device of claim 1, wherein the word line driver and the bit line driver are configured to output the first voltage and the second voltage higher than the first voltage, respectively, depending on characteristics of the memory cell, and

4. The semiconductor memory device of claim 1, further comprising:
a voltage setting module configured to store voltage setting information associated with the first voltage and the second voltage, wherein
the world line driver configured to generate the first voltage based on the voltage setting information; and
the bit line driver configured to generate the second voltage based on the voltage setting information.

5. The semiconductor memory device of claim 4, wherein the voltage setting module comprises a fuse circuit configured to store the voltage setting information.

6. The semiconductor memory device of claim 4, wherein
the word line driver comprises:
an inverter circuit comprising a P-channel insulated gate field effect transistor and an N-channel insulated gate field effect transistor; and
a step-down module connected to an output terminal of the inverter circuit, and
the word line driver is configured to adjust a resistance value of the step-down module based on the voltage setting information, and to output a midpoint potential between a supply voltage and a ground voltage as the first voltage with the P-channel insulated gate field effect transistor and the step-down module, when a word line is selected.

7. The semiconductor memory device of claim 6, wherein the P-channel insulated gate field effect transistor and the N-channel insulated gate field effect transistor are either Metal-Oxide-Semiconductor (MOS) transistors or Metal-Insulator-Semiconductor (MIS) transistors.

8. The semiconductor memory device of claim 4, wherein
the bit line driver comprises a bootstrap circuit which is a negative potential generator,
the bootstrap circuit comprises a capacitor and a charging or discharging circuit connected to a first end of the capacitor, and configured to adjust the second voltage on the first end of the capacitor when a second end of the capacitor is inverted from a high level to a low level, by adjusting a charging current of the charging circuit or a discharging current of the discharging circuit based on the voltage setting information.

9. A semiconductor memory device, comprising:
a memory cell array comprising a plurality of word lines, a plurality of bit lines intersecting the plurality of word lines, and a plurality of memory cells connected to the intersections of the plurality of word lines and the plurality of bit lines;
a word line driver configured to drive a selected word line to a positive first voltage when data is written to the memory cell; and
a bit line driver configured to drive a selected bit line to a negative second voltage corresponding to the first voltage when the data is written to the memory cell,
wherein the word line driver comprises:
an inverter circuit comprising a first P-channel insulated gate field effect transistor and a first N-channel insulated gate field effect transistor; and
a step-down module connected to an output terminal of the inverter circuit, and
wherein the word line driver is configured to output a midpoint potential between a supply voltage and a ground voltage as the first voltage with the first P-channel insulated gate field effect transistor and the step-down module when a word line is selected.

10. The semiconductor memory device of claim 9, wherein each memory cell comprises an SRAM cell comprising a data retention module, and a transfer transistor connected between the data retention module and one of the bit lines, the transfer transistor comprising a gate connected to one of the word lines.

11. The semiconductor memory device of claim 10, wherein the first P-channel insulated gate field effect transistor and the first N-channel insulated gate field effect transistor are either MOS transistors or MIS transistors.

12. The semiconductor memory device of claim 9, wherein the step-down module comprises a second P-channel insulated gate field effect transistor between the output terminal of the inverter circuit and the ground potential.

13. The semiconductor memory device of claim 9, wherein the step-down module comprises the second P-channel insulated gate field effect transistor and a resistance connected in series between the output terminal of the inverter circuit and the ground potential.

14. The semiconductor memory device of claim 9, wherein
the bit line driver comprises a bootstrap circuit which is a negative potential generator,
the bootstrap circuit comprises a capacitor and a charging or discharging circuit connected to a first end of the capacitor, and configured to adjust the second voltage on the first end of the capacitor when a second end of the capacitor is inverted from a high level to a low level, by adjusting a charging current of the charging circuit or a discharging current of the discharging circuit based on the voltage setting information.

15. A semiconductor memory device, comprising:
a regulator configured to step down a supply voltage and to generate a positive first voltage; and
a memory block configured to receive the first voltage from the regulator in order to write data and to read data, wherein
the memory block comprises:
a memory cell array comprising a plurality of word lines, a plurality of bit lines intersecting the plurality of word lines, and a plurality of memory cells connected to the intersections of the plurality of word lines and the plurality of bit lines;
a word line driver configured to drive a selected word line to the positive first voltage when data is written to the memory cells; and
a bit line driver configured to drive a selected bit line to a negative second voltage corresponding to the first voltage when the data is written to the memory cells.

16. The semiconductor memory device of claim 15, wherein each memory cell comprises an SRAM cell comprising a data retention module, and a transfer transistor connected between the data retention module and one of the bit lines, the transfer transistor comprising a gate connected to one of the word lines.

17. The semiconductor memory device of claim 15, wherein the word line driver and the bit line driver are configured to output the positive first voltage and the negative second voltage higher than the positive first voltage respectively, depending on characteristics of the memory cell.
